(19) United States
(12) Patent Application Publication
(10) Pub. No.: US 2014/0103451 A1
(43) Pub. Date: Apr. 17, 2014

(54) FINFET CIRCUITS WITH VARIOUS FIN HEIGHTS

(71) Applicant: INTERNATIONAL BUSINESS MACHINES CORP, Armonk, NY (US)

(72) Inventors: Qiqing C. Ouyang, Yorktown Heights, NY (US); Pranita Kerber, Slingerslands, NY (US); Alexander Reznicek, Troy, NY (US)

(73) Assignee: INTERNATIONAL BUSINESS MACHINES CORPORATION, Armonk, NY (US)

(21) Appl. No.: 13/654,010

(22) Filed: Oct. 17, 2012

(51) Int. Cl. H01L 27/088

(52) U.S. Cl. 257/401; 257/E27.06

(57) ABSTRACT

A fin field-effect transistor (finFET) assembly includes a first finFET device having fins of a first height and a second finFET device having fins of a second height. Each of the first and second finFET devices includes an epitaxial fill material covering source and drain regions of the first and second finFET devices. The epitaxial fill material of the first finFET device has a same height as the epitaxial fill material of the second finFET device.

### BACKGROUND

The present invention relates to fin field-effect transistors (finFETs) having fins of varying heights. In particular, the present invention relates to forming fins of varying heights, forming epitaxial material on the fins of varying heights, and forming level contact surfaces on the finFETs.

Field-effect transistors (FETs) generate an electric field, by a gate structure, to control the conductivity of a channel between source and drain structures in a semiconductor substrate. The source and drain structures may be formed by doping the semiconductor substrate, a channel region may extend between the source and the drain on the semiconductor substrate and the gate may be formed on the semiconductor substrate between the source and drain regions.

Dimensions of finFET devices may be limited by various design considerations including available geographical space in a circuit for the finFET device and required ratios of various devices in the circuit. For example, in a static random access memory (SRAM) device, pull-up and pull-down devices must have widths (corresponding to heights in finFET devices) of predetermined ratios with respect to each other. However, the device width for a finFET device is determined by the number of fins multiplied by a fin height. Since the number of fins may be limited due to constraints on the size of the finFET circuit, the device width ratio may be limited for fins with only height.

In addition, the source/drain regions for the current finFET technology often have different height if fins are merged with an epitaxial layer. This is due to different epitaxial processes for nFETs and pFETs. For fins with different heights, this problem will be even more significant. This could result in silicide loss during the contact hole opening by reactive ion etching (RIE) and may cause higher contact resistance.

### SUMMARY

Embodiments of the invention include a fin field-effect transistor (finFET) assembly includes a first finFET device having fins of a first height and a second finFET device having fins of a second height. Each of the first and second finFET devices includes an epitaxial fill material covering source and drain regions of the first and second finFET devices. The epitaxial fill material of the first finFET device has a same height as the epitaxial fill material of the second finFET device.

Additional embodiments include a method of forming a fin field effect transistor (finFET). The method includes forming a plurality of fins of varying heights on a substrate and forming a first gate structure on one or more fins of a first height to form a first finFET structure and a second gate structure on one or more fins of a second height to form a second finFET structure. The method further includes epitaxially forming an epitaxial fill material on the one or more fins of the first finFET structure and the second finFET structure. The epitaxial fill material of the first finFET structure is formed to have a same height as the epitaxial fill material of the second finFET structure.

Additional features and advantages are realized through the techniques of the present invention. Other embodiments and aspects of the present invention are described in detail herein and are considered a part of the claimed invention. For a better understanding of the invention with the advantages and the features, refer to the description and to the drawings.

BRIEF DESCRIPTION OF THE SEVERAL VIEWS OF THE DRAWINGS

The subject matter of the invention is particularly pointed out and distinctly claimed in the claims at the conclusion of the specification. The forgoing and other features, and advantages of the invention are apparent from the following detailed description taken in conjunction with the accompanying drawings in which:

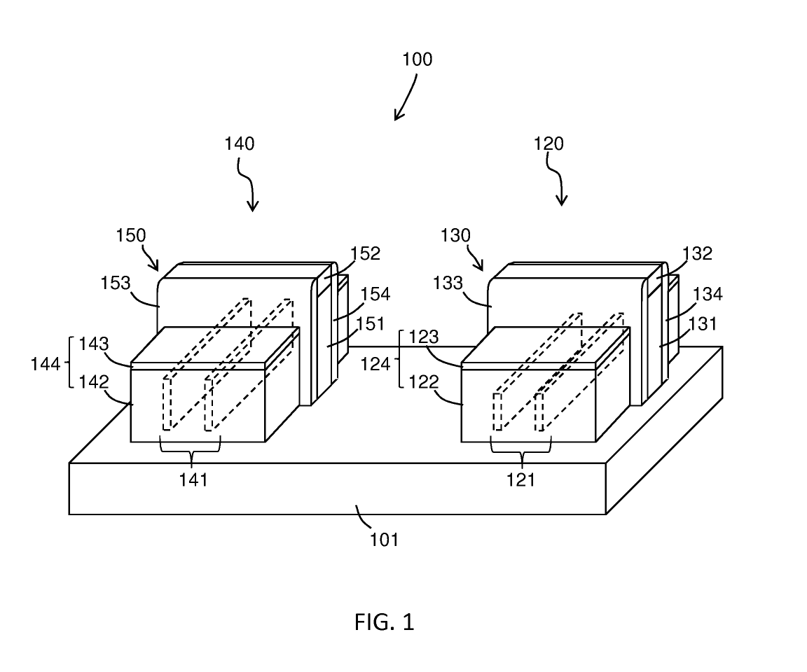

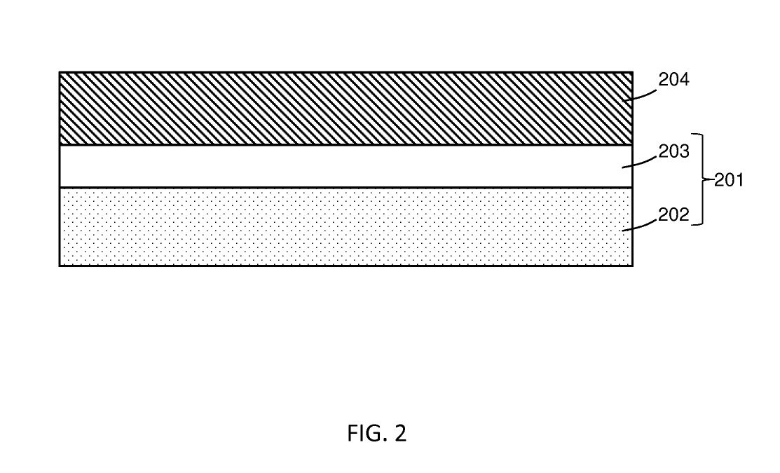

FIG. 1 illustrates a finFET assembly or circuit according to one embodiment of the present invention;

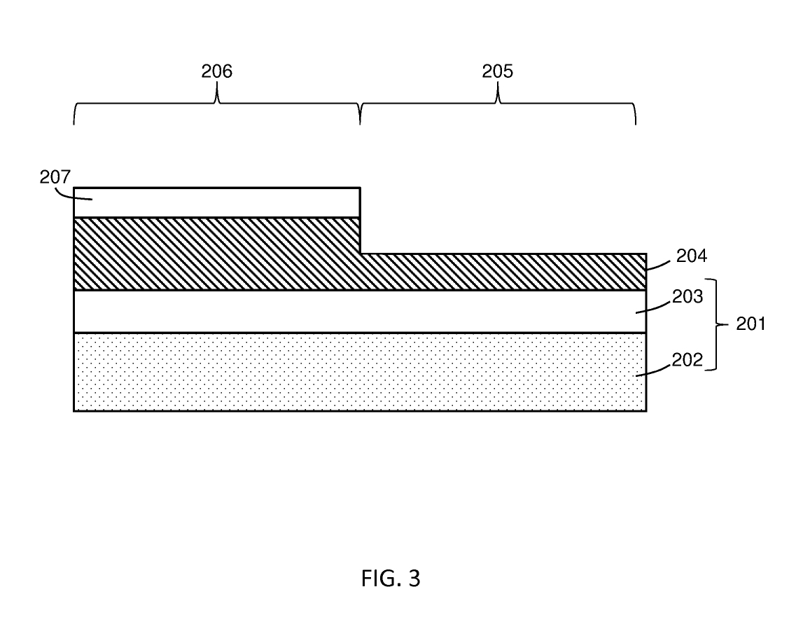

FIG. 2 illustrates forming a silicon-on-insulator (SOI) layer on a substrate;

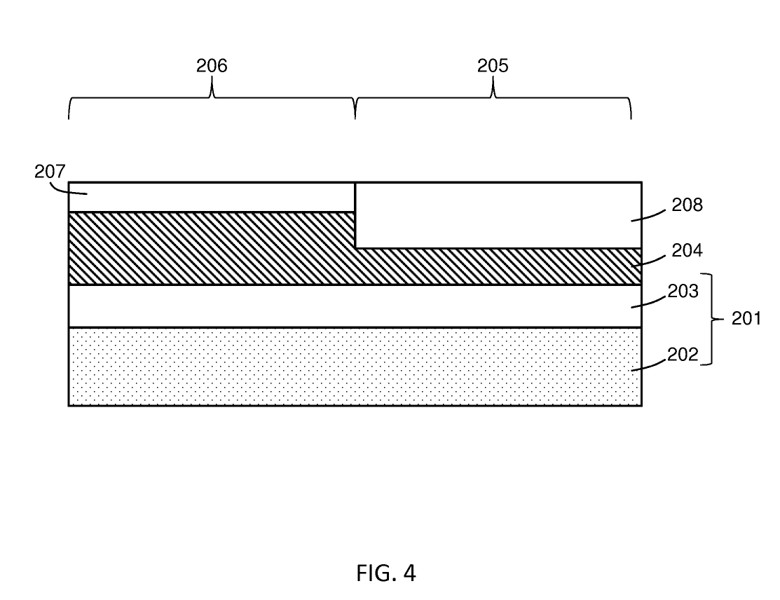

FIG. 3 illustrates removing a portion of the SOI layer;

FIG. 4 illustrates forming mask layers;

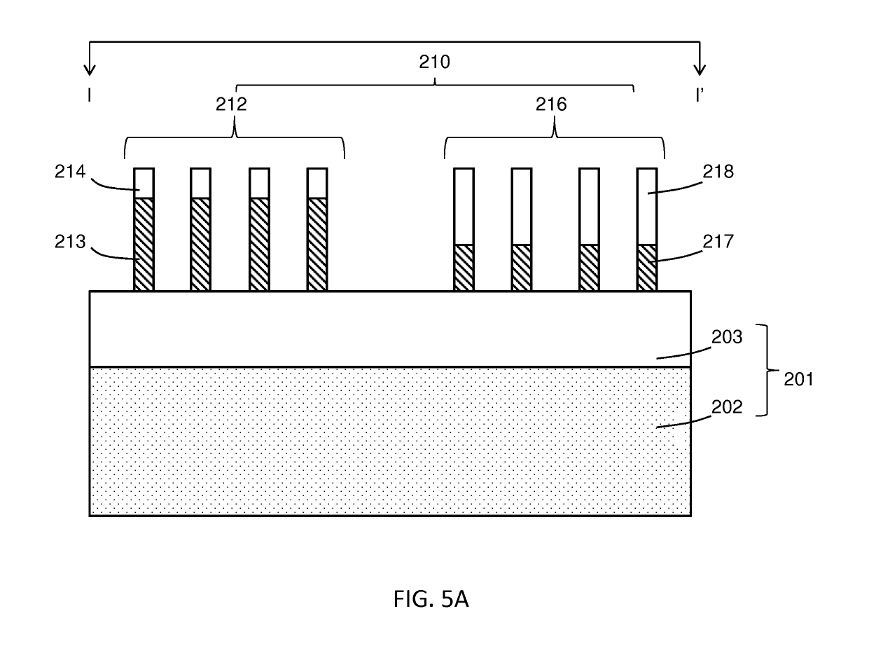

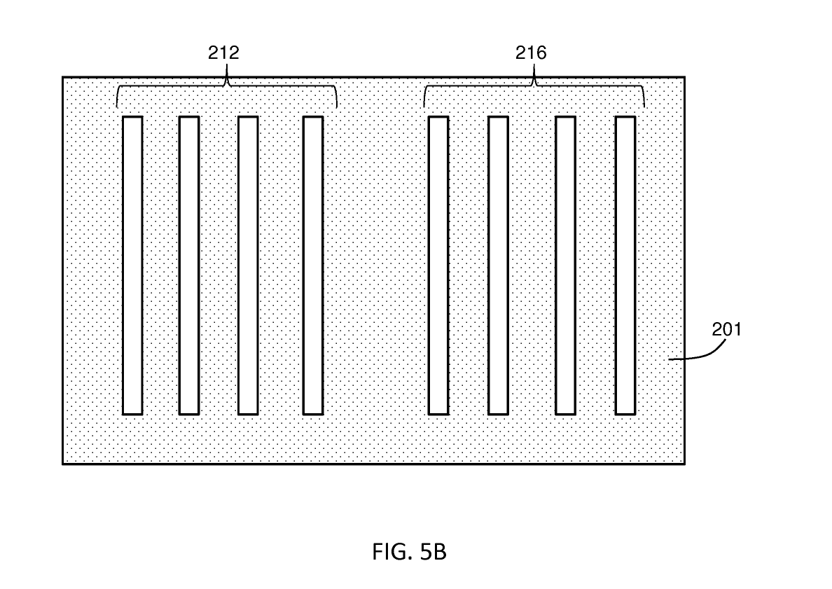

FIG. 5A illustrates a side view of forming fin structures according to an embodiment;

FIG. 5B illustrates a top view of forming fin structures;

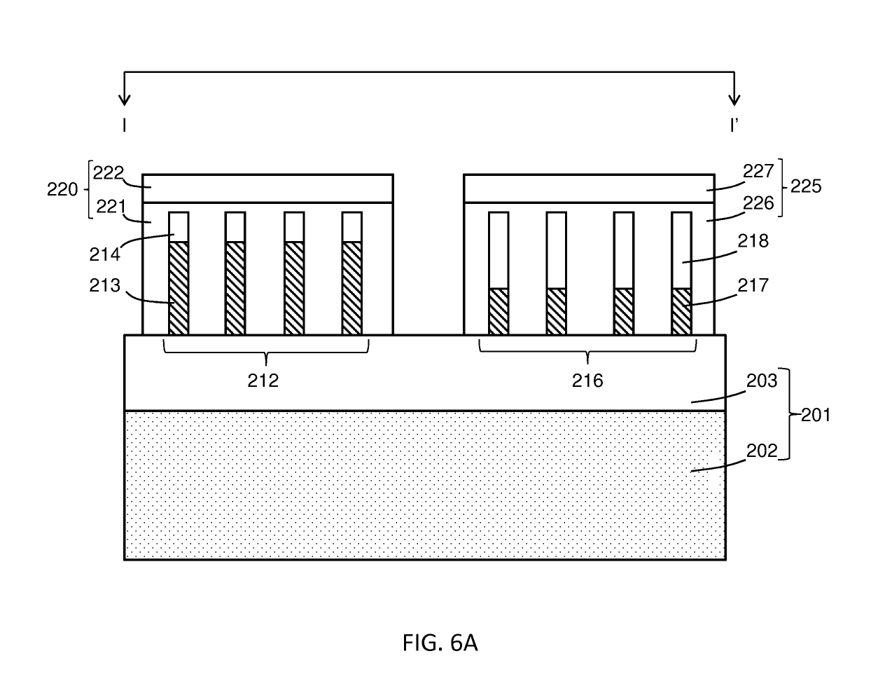

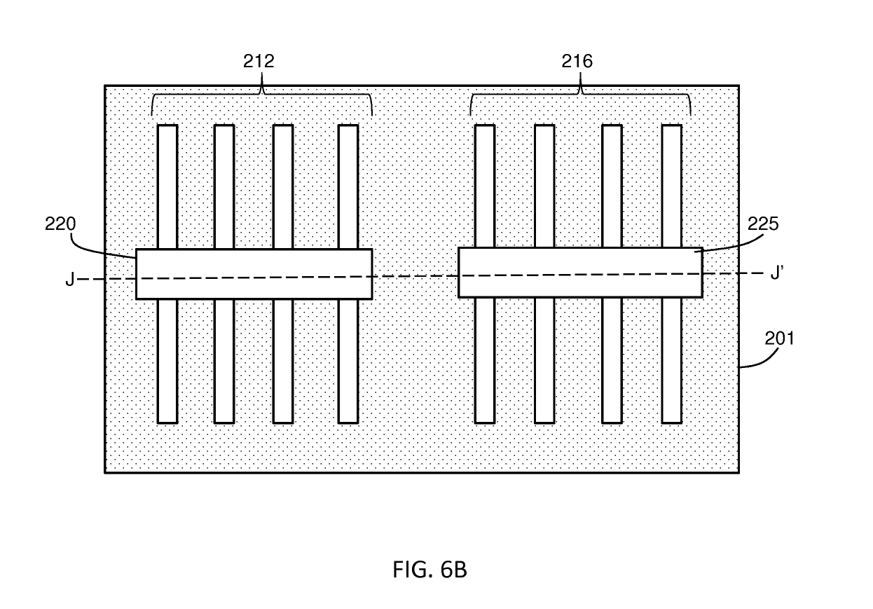

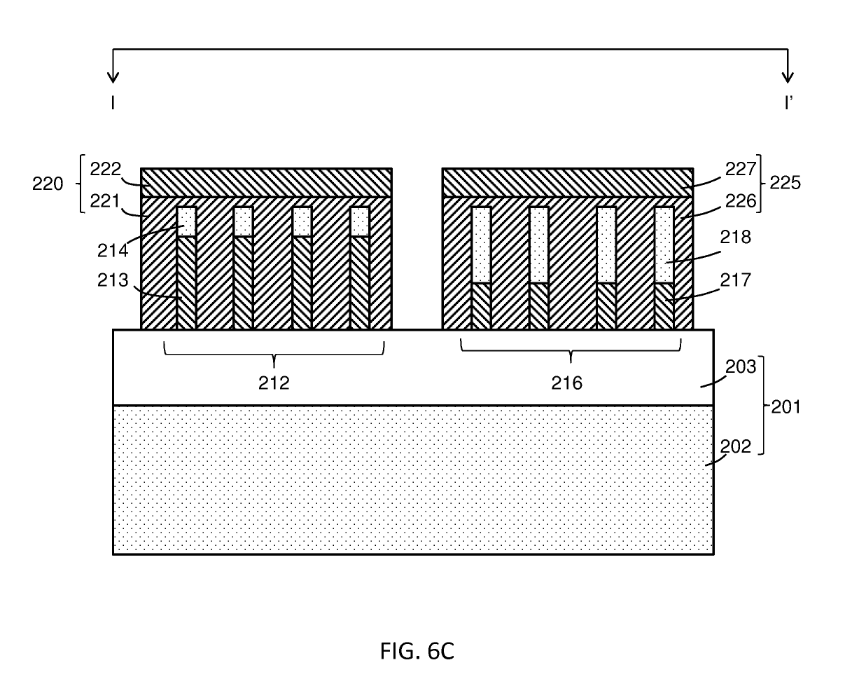

FIG. 6A illustrates a side view of forming a gate structure;

FIG. 6B illustrates a top view of forming the gate structure;

FIG. 6C illustrates a cross-section side view of forming the gate structure;

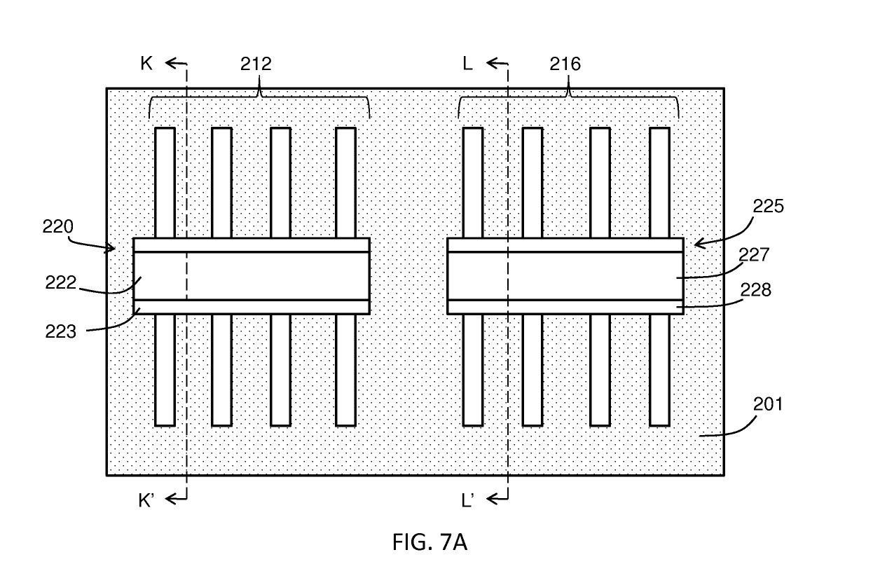

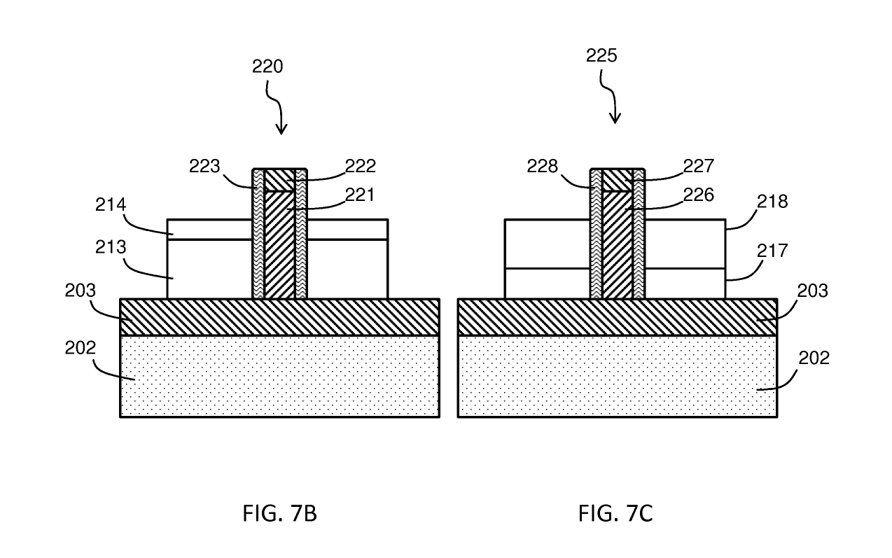

FIG. 7A illustrates a top view of forming insulating layers on the gate structure;

FIG. 7B illustrates a cross-section view of forming the insulating layers on the gate structure;

FIG. 7C illustrates another cross-section view of forming the insulating layers on the gate structure;

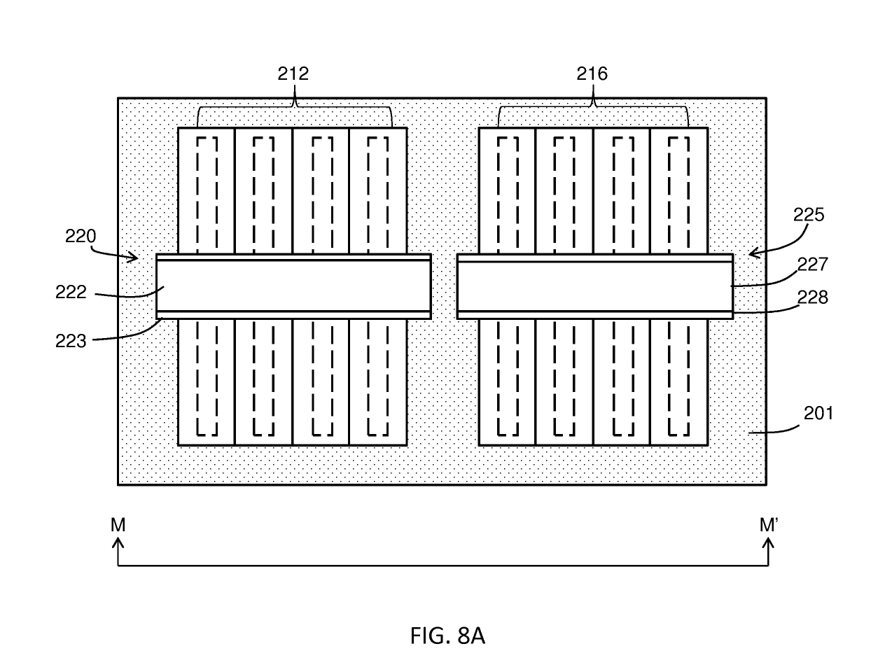

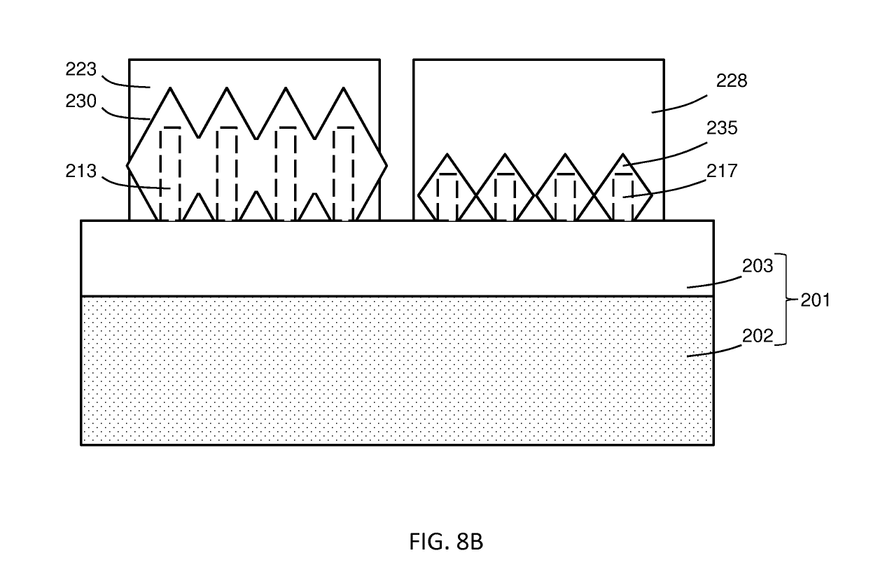

FIG. 8A illustrates a top view of forming epitaxial layers on fins;

FIG. 8B illustrates a side view of forming the epitaxial layers on the fins;

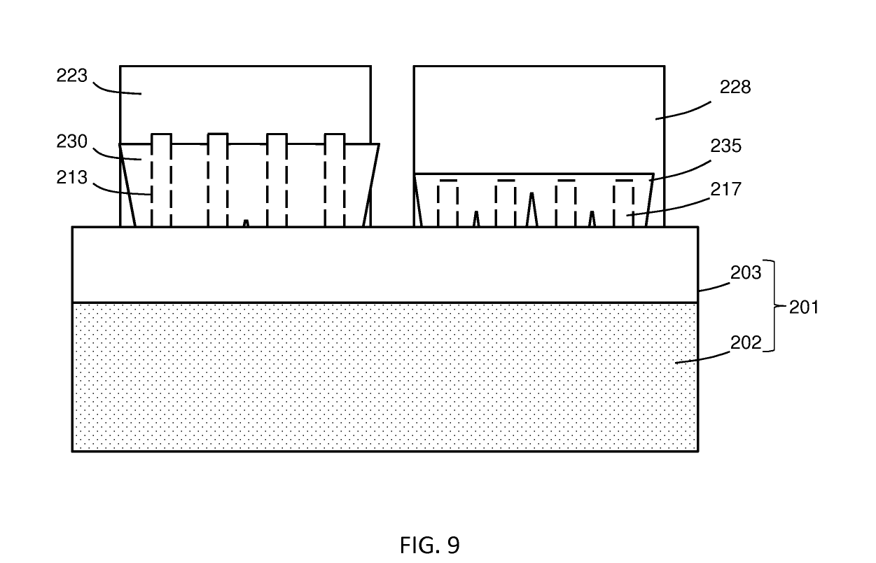

FIG. 9 illustrates annealing the epitaxial layers;

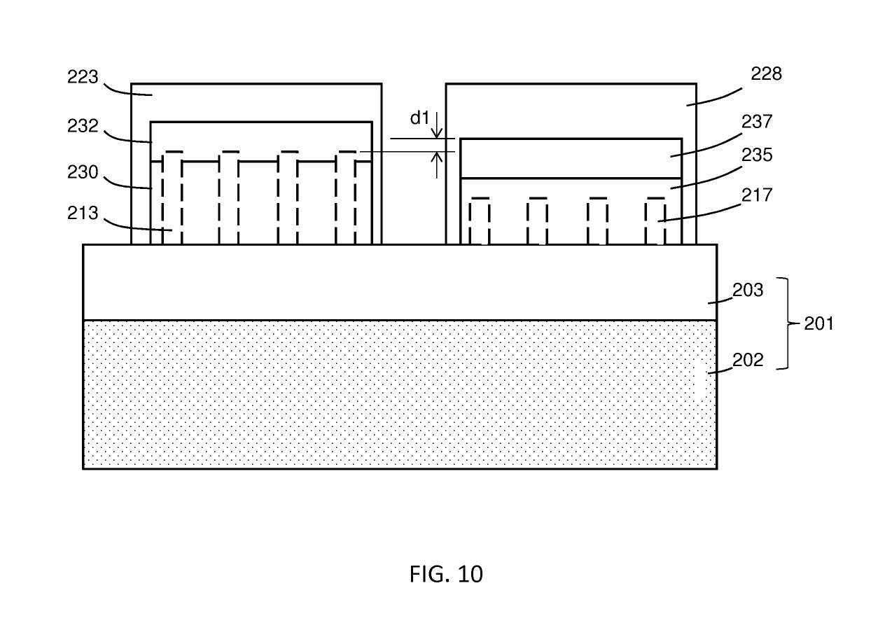

FIG. 10 illustrates forming another epitaxial layer on the annealed epitaxial layer;

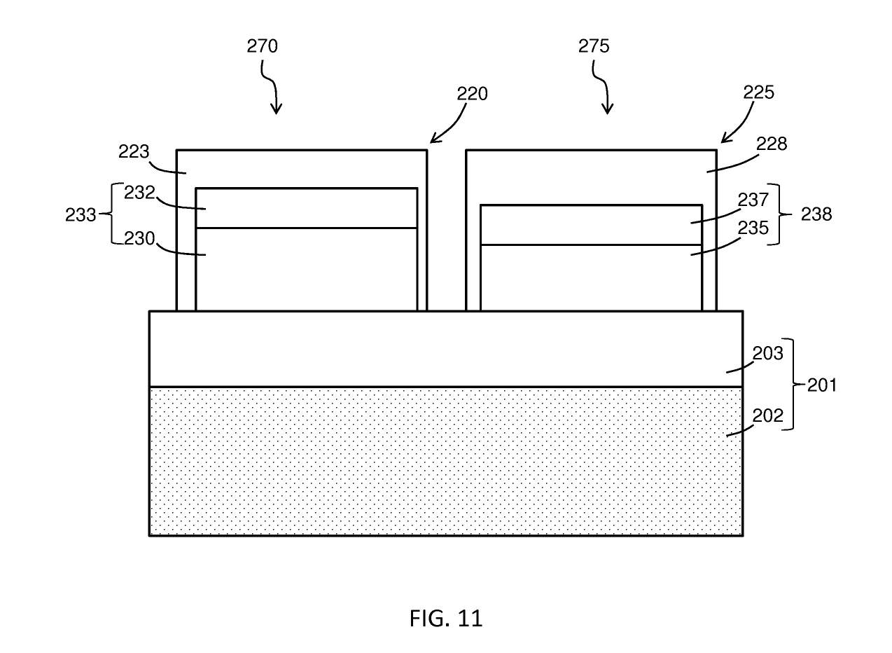

FIG. 11 illustrates planarizing the epitaxial layer;

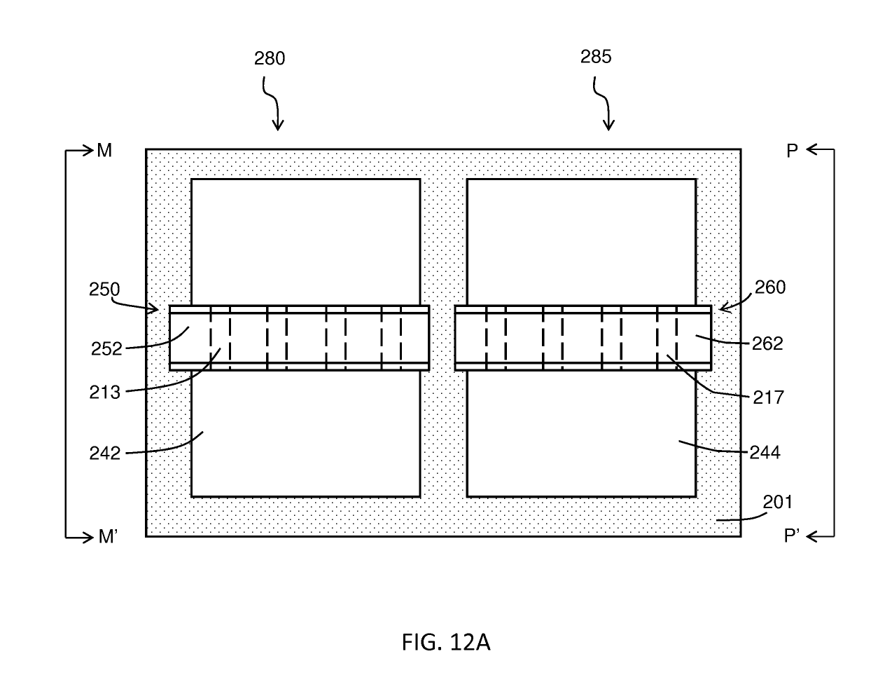

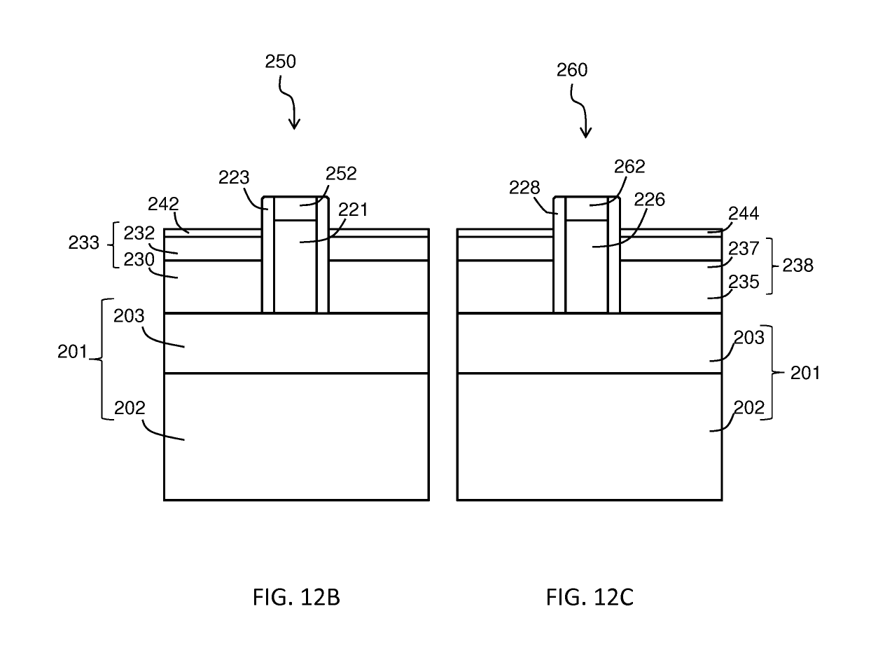

FIG. 12A illustrates a top view of forming a contact layer;

FIG. 12B illustrates a side view of forming the contact layer; and

FIG. 12C illustrates another side view of forming the contact layer.

### DETAILED DESCRIPTION

Dimensions of finFET devices may be limited by required dimension ratios with other devices, by space requirements of a circuit, and other design considerations. Embodiments of the present invention relate to finFET devices having fins of varying heights joined by an epitaxial layer.

FIG. 1 illustrates a fin field-effect transistor (finFET) assembly 100 according to an embodiment of the present invention. The finFET assembly 100 includes a substrate 101, a first finFET device 120 and a second finFET device 140. The first finFET device 120 includes merged source/drain (SD) regions 124, including a filling layer 122 and a contact layer 123. A gate structure 130 is located between the SD regions 124. In embodiments of the invention, the finFET assembly 100 may represent an electrical circuit connecting the finFETs 120 and 140, a wafer on which the finFETs 120 and 140 are both fabricated or any other assembly including multiple finFETs 120 and 140 formed on the same substrate 101.

The second finFET device 140 also includes merged source/drain (SD) regions 144, including a filling layer 142 and a contact layer 143. The second finFET device 140 also includes a gate structure 150 is located between the SD regions 144.

The first finFET device 120 is formed around first fins 121 located on the substrate 101, and the second finFET device 140 is formed around second fins 140 located on the substrate 101. The first fins 121 may have a first height and the second fins 141 may have a second height different than the first fins 121. The substrate 101 may include one or more of an insulating material and a semiconductive material, such as a silicon-based material. The fins 121 and 141 may comprise a silicon-based material. In one embodiment, the filling material 122 and 142 may be an epitaxial layer, or a layer of silicon, which may be doped silicon, grown epitaxially on the first and second fins 121 and 141. In the present specification and claims, the filling material 122 and 142 may be referred to as a fill material, filling material, epitaxial fill material, or the like. The contact layers 123 and 143 may include a silicide layer. The filling layers 122 and 142 may be semiconductor layers.

The first gate structure 130 of the first finFET device 120 may include a gate stack layer 131 and a contact layer 132 on the gate stack layer 131. The gate stack layer may include one or more layers of high-dielectric constant (high-k) material under one or more multi-layer metals, doped polysilicon, and silicide. The gate structure 130 may also include insulating layers 133 and 134 disposed on sidewalls of the gate stack layer 131 and contact layer 132. Similarly, the second gate structure 150 of the second finFET device 140 may include a gate stack layer 151 and a contact layer 152 on the gate stack layer 151. The gate structure 150 may also include insulating layers 153 and 154 disposed on sidewalls of the gate stack layer 131 and contact layer 132.

In embodiments of the present invention, the fins 121 and 141 may have varying fin heights to vary the conductive characteristics of the finFET devices 120 and 140, while maintaining a height of the contact layers 123 and 143 the same. In addition, as discussed below, the finFET device 100 may have fins 121 and 141 or fin structures having different height characteristics inside the gate structures 130 and 150 from outside the gate structures 130 and 150. Accordingly, conductive characteristics of finFET devices 120 and 140 on the same finFET assembly 100, such as a same wafer or finFET circuit, may be varied while maintaining at a same level the physical height dimensions of the merged SD regions 124 and 144 of the finFET devices 120 and 140.

FIGS. 2 to 12C illustrate a process of forming a finFET device according to one embodiment of the present invention. Referring to FIG. 2, a substrate 201 includes a base substrate layer 202 and an insulation layer 203 formed on the based substrate layer 202. A semiconductor layer 204, such as a silicon-on-insulator (SOI) layer, is formed on the insulating layer 203. In the present specification and claims, the semiconductor layer 204 may also be referred to as an SOI layer 204, although embodiments encompass semiconductor materials other than silicon. The base substrate 202 may be made of any semiconductor material including: silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. In general, base substrate 202 and semiconductor layer 204 may include either identical or different semiconducting materials with respect to chemical composition, dopant concentration and crystallographic orientation. The semiconductor layer 204 may be p-doped or n-doped with a dopant concentration in the range of 1×10¹⁵-1×10¹⁸/cm³, preferably about 1×10¹⁵/cm³. The SOI layer 130 may be about 50-300 nm thick, preferably about 100 nm.

Although FIGS. 2 to 12C illustrate an embodiment related to an SOI device, embodiments of the present invention may be formed by any class of device, such as bulk silicon devices.

In one embodiment, the base substrate layer 202 is a silicon layer. In addition, the insulating layer 203 may be a buried oxide (BOX) layer, and in the present specification, the insulating layer 203 will be referred to as a BOX layer 203. The BOX layer 203 may be formed from any of several dielectric materials. Non-limiting examples include oxides, nitrides, and oxynitrides of silicon, and combinations thereof. Oxides, nitrides and oxynitrides of other elements are also envisioned. Further, the BOX layer 203 may include crystalline or non-crystalline dielectric material. The box layer 203 may be about 50-500 nm thick, preferably about 200nm. The semiconductor layer 204 may be made of any of the several semiconductor materials possible for base substrate 202.

FIG. 3 illustrates forming a first hard mask 207 on a first portion 206 of the SOI layer 204. The hard mask 207 may be made, for example, of a dielectric material such as silicon nitride (SiN) or silicon oxide (SiO₂) or a high-dielectric-constant (high-k) material. A second portion 205 of the SOI layer 204 that is not covered by the hard mask layer 207 may be removed. In one embodiment, the second portion 205 is cut back by an etching process, such as a reactive ion etching (RIE) process. In another embodiment, thinning can be performed by oxidation of the exposed Si area and removal of the oxide. In yet another embodiment, thickening of the SOI layer 204 may be performed, such as by an epitaxial growth process, to increase a fin height of the second portion 205 instead of removing material from the second portion 205.

FIG. 4 illustrates forming a second hard mask 208 on the exposed short portion 205 of the SOI layer 204. The second hard mask 208 may be formed to have an upper surface that is co-planar with the upper surface of the first hard mask 207. In one embodiment, the first hard mask 207 is removed and a new hard mask is formed to cover both the tall portion 206 and the short portion 205 of the SOI layer 204. In one embodiment, the first and second hard masks 207 and 208 (or, in one embodiment, the single hard mask layer comprising the portions 207 and 208) is planarized, such as with a chemical-mechanical planarization (CMP) process to form an even upper surface. In another embodiment, the second hard mask 208 is formed on both the first hard mask 207 and the exposed short portion 205 and the second hard mask 208, and in some embodiments the first hard mask 207, is planarized to form the flat upper surface illustrated in FIG. 4.

FIGS. 5A and 5B illustrate forming fin structures 210. FIG. 5A illustrates a side view and FIG. 5B illustrates a top view as seen from line I-I′ of FIG. 5A. The fin structures 210 may be formed by patterning and etching the mask layers 207 and 208 and the SOI layer portions 205 and 206. The resulting fin structures 210 include first fin structures 212 and second fin structures 216. The first fin structures 212 include tall silicon portions 213 and hard mask portions 214 on the tall silicon portions 213. The second fin structures 216 include short fins 217 and hard mask portions 218 on the short fins 217. While fins of significantly different heights are illustrated for purposes of description, embodiments of the present invention encompass fins of any difference in height.

FIGS. 6A to 6C illustrate forming preliminary gate structures 220 and 225. FIG. 6A illustrates a side view, FIG. 6B illustrates a top view as seen from line I-I′ of FIG. 6A, and FIG. 6C illustrates a cross-section view as seen from line J-J′ of FIG. 6B. A first preliminary gate structure 220 is formed on the tall fin structure 212. The first preliminary gate structure 220 includes a gate channel or electrode 221 and a gate hard mask layer 222. In one embodiment, the gate hard mask is a nitride, a dielectric, or any combination of dielectric layers. The gate channel 221 and gate hard mask layer 222 may be formed by deposition or any other suitable method. In a similar manner, the second preliminary gate structure 225, including the gate channel or electrode 226 and the gate hard mask layer 227 may be formed on the short fins 216. In some embodiments, the gate 220 may be formed using a gate-first process, in which case gate electrode 222 may further include a gate dielectric layer, work-function metal layers, and a metal fill layer. The gate dielectric layer may be made of metal oxides, metal silicates, metal nitrides, transition metal oxides, transition metal silicates, transition metal nitrides, or combinations thereof, and may be approximately 1 nm-5 nm thick.

Examples of gate dielectric layer materials include silicon dioxide, hafnium oxide, and aluminum oxide. The work-function metal layers may comprise multiple metal-containing layers and may be made of titanium nitride, tantalum nitride, or titanium-aluminum and may be 20-100 angstroms thick. The metal fill layer may be made of, for example, silicon, aluminum, copper, tungsten, or some combination thereof. Other embodiments may include more or less metal layers depending on the application and types of device being formed. The composition of each metal layer may also vary and the process of selecting the material for each metal layer is known in the art.

In some other embodiments, the gate 220 may be formed using a gate-last process, in which case gate electrode 222 may include a sacrificial layer such as silicon serve as a placeholder for the replacement gate formed after later processing steps. In embodiments where a gate-last process is used, gate electrode 222 may be removed and a replacement metal gate may be formed prior to the formation of a contact stud on the gate 220.

FIGS. 7A to 7C illustrate forming insulation layers 223 and 228 on the preliminary gate structures 220 and 225. FIG. 7A illustrates a top view and FIGS. 7B and 7C illustrate cross-section views as seen along lines K-K′ and L-L′ of FIG. 7A, respectively.

The insulation layer 223 is formed on the sides of the preliminary gate structure 220 over the fin structures 212. Likewise, the insulation layer 228 is formed on the sides of the preliminary gate structure 225 over the fin structures 216. In one embodiment the insulation layers 223 and 228 are formed of silicon nitride (SiN). In one embodiment, the material that makes up the insulating layers 223 and 228 is different than the material making up the hard masks 222 and 227.

FIGS. 8A and 8B illustrate forming epitaxial layers 230 and 235 on the fin structures 212 and 216, respectively. FIG. 8A is a top view and FIG. 8B is a side view seen from lines M-M′ of FIG. 8A.

In FIGS. 8A and 8B, the hard mask layers 214 and 218 of the fin structures 212 and 216 are removed, such as by etching. In one embodiment, the hard mask layers 214 and 218 are removed by an RIE process. Since the portion of the fin structures 212 and 216 located in the preliminary gate structure 220 are covered by the hard mask 224, the portion of the fin structures 212 and 216 located within the preliminary gate structure 220 still retains the hard mask layers 214 and 218. In other words, while the hard mask layers 214 of the portions of the fin structures 212 and 216 are removed to expose fins 213 and 217 having varying heights, the portions of the fin structures 212 and 216 within the preliminary gate structure 220 may have a same height.

In an alternative embodiment, the hard mask layers 214 and 218 are removed from the fin structures 212 and 216 prior to forming the preliminary gate structure 220, so that the preliminary gate structures 220 and 225 are formed directly on the fins 213 and 217, respectively. In such an embodiment, the height of the fins 213 is the same on each side of the preliminary gate structure 220 and through the preliminary gate structure 220. Similarly, the height of the fins 217 is the same on each side of the preliminary gate structure 225 and through the preliminary gate structure 225. In other words, embodiments of the present invention relate to both finFET structures, in which a mask is maintained on the fins through the gate structures, and tri-gate structures, in which a mask is removed from the fins prior to forming the gate structures. Alternatively, trigate structures could also be formed during the replacement gate process wherein after etching the gate hardmask and dummy gate layers, the fin hardmask is etched prior to gate layer deposition.

An epitaxial layer 230 is formed on the fins 213, and an epitaxial layer 235 is formed on the fins 217. The epitaxial layers 230 and 235 may be formed, for example, of silicon germanium (SiGe) to form a positive FET (PFET) device. In one embodiment, a top of the fins 213 and 217 may have a one hundred (100) crystal orientation, and sides of the fins 213 and 217 may have a one hundred ten (110) crystal orientation. Based on the different orientations on different surfaces, forming the epitaxial layers may result in diamond-shaped epitaxial layers. In one embodiment, the epitaxial layers 230 and 235 are in-situ doped. In FIGS. 8A and 8B, the dashed lines represent the position of the fins 213 and 217 encased within the epitaxial layers 230 and 235.

FIG. 9 illustrates a side view of a finFET assembly subjected to annealing of the epitaxial layers 230 and 235, as seen from the ends of the fins 213 and 217. In particular, the finFET assembly may be subjected to a reflow annealing process to reflow the epitaxial layers 230 and 235. The reflow annealing process may result in the epitaxial layers 230 and 235 merging the multiple separately-formed, diamond-shaped, epitaxial layer portions illustrated in FIGS. 8A and 8B to form a contiguous epitaxial layers 230 and 235, respectively. In one embodiment, the wafer including the finFET assembly is annealed in hydrogen. The wafer may be annealed at a temperature of 750 degrees Celsius (C) or greater, such as at a temperature of 800 degrees C. The annealing may be performed for five to ten minutes, or for any period of time, depending upon the temperature, sufficient to perform a reflow process. The reflow may be performed such that the silicon, or the gate channels 221 and 226 in the preliminary gate structures 220 and 240 are maintained intact. In addition, the fins 213 and 217 may also remain substantially intact. In other words, while some deformation of the fins 213 and 217 may occur, such as rounding of corners, the fins 213 maintain a same general shape including a height greater than the height of the fins 217.

FIG. 10 illustrates performing a second epitaxial process to grow epitaxial layers 232 and 237 on the reflow-annealed layers 230 and 235, respectively. The epitaxial layer 237 is grown to a height that is above the height of the tall fins 213, by at least a predetermined height d1 greater than zero. While FIG. 10 illustrates fins 213 and 217 having only two heights, fins of any number of heights may be formed. Accordingly, in embodiments of the present invention, second epitaxial layers are formed on the reflow-annealed epitaxial layers such that a lowest portion of the epitaxial layers is higher than a tallest fin among all of the finFET devices in a finFET circuit or assembly. In addition, while FIG. 10 illustrates the epitaxial layer 237 being higher than the fins 213, in one embodiment, the epitaxial layer 237 is flush with the tall fins 213, or in one embodiment d1 is zero. Epitaxial growth and reflow annealing may be performed once or more than once, as needed. The dashed lines in FIG. 10 illustrate the portions of the fins 213 and 217 encased within the epitaxial layers 230, 232, 235, and 237 respectively.

As illustrated in FIG. 10, embodiments of the present invention encompass fins and epitaxial layer heights such that one or more fins or sets of fins extends through multiple stacked epitaxial layers or is enclosed within only one epitaxial layer. For example the epitaxial layer 230 may be in-situ doped with an acceptor-type dopant while the epitaxial layer 235 may be in-situ doped with donor-type dopant. In addition, embodiments encompass epitaxial layers having different properties, such as different dopant levels. For example, the lower epitaxial layers 230 and 235 may be doped to a lesser extent, or in lower concentrations, than the upper epitaxial layers 232 and 237.

FIG. 11 illustrates etching back at least a portion of the epitaxial layer 232 such that the upper surface of the epitaxial layer 232 is co-planar with the upper surface of the epitaxial layer 237. The merged SD regions 233 on each side of the gate structure 220 may be etched back, and the merged SD regions 233 of the first interim finFET device 270 may have a same height as each of the merged SD regions 238 of the second interim finFET device 275. In one embodiment, a mask or other blocking structure may be formed on the epitaxial layer 237. As illustrated in FIG. 11, spaces between the fins 213 and 217 may be entirely filled in by the epitaxial layers 230 and 235 in two or more stages of epitaxial growth.

FIGS. 12A to 12C illustrate forming contact layers 242 and 244 according to an embodiment. FIG. 12A is a top view and FIGS. 12B and 12C are side views along lines N-N′ and P-P′, respectively, of FIG. 12A. In particular, the hard masks 222 and 227 are removed from the gate structures 220 and 225 and contact layers 252 and 262 are formed in the gate structures 220 and 225, respectively. In addition, a contact layers 242 and 244 are formed on the merged SD regions 233 and 238. In one embodiment, the contact layers 252, 262, 242 and 244 are formed of a same material, and may be formed in a same process. In particular, in one embodiment, the contact layers 252, 262, 242 and 244 are silicide layers formed in a silicide annealing process. Additional contact layers, such as metal layers, may be formed on the silicide layers 252, 262, 242 and 244.

While an embodiment has been described in which a single finFET device is formed, embodiments of the present invention encompass forming any number of finFETs, which may include simultaneous formation of PFETs and NFETs. In such an embodiment, one FET, such as a PFET, may be blocked while the epitaxial layers of the other FET, such as the NFET are formed and vice versa. Accordingly, the epitaxial layers of different types of FETs may be formed with different doping levels.

Although illustrated embodiments show separate finFET devices having different fin heights, embodiments of the present invention encompass finFET devices having fins of varying heights within a same finFET device. In addition, although embodiments have been illustrated with multiple fins in each finFET device, embodiments of the invention encompass any number of fins, from as few as one to as many as design specifications of a circuit allow.

According to embodiments of the invention, finFET devices and assemblies may be formed having fins of varying heights to provide flexibility in designing FET circuits. Filling material, such as an epitaxial layer, may be formed to provide contact surfaces on the source and drain regions of the finFETs. The contact surfaces of the different finFET devices of the same finFET assembly, circuit or wafer may have constant heights, even when the fins have varying heights.

While a process has been illustrated with reference to various figures, embodiments of the present invention encompass variations to the process, such as adding steps, omitting steps and rearranging an order in which steps are performed. In addition, while some materials have been described by way of example, embodiments of the present invention encompass any materials suited for the described purpose, such as forming an insulator material, forming a semiconductive material, or forming a conductive material, respectively.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments of the present invention have been chosen and described in order to best explain the principles of the invention and the practical application, and to enable others of ordinary skill in the art to understand the invention for various embodiments with various modifications as are suited to the particular use contemplated.

While exemplary embodiments of the invention have been described, it will be understood that those skilled in the art, both now and in the future, may make various improvements and enhancements which fall within the scope of the claims which follow. These claims should be construed to maintain the proper protection for the invention first described.

1. A fin field-effect transistor (finFET) assembly, comprising:
a first finFET device having first fins of a first height; and
a second finFET device having second fins of a second height different from the first height, as measured from a same, substantially flat, surface on which each of the first fins and the second fins are formed, each of the first and second finFET devices comprising an epitaxial fill material covering source and drain regions of the first and second finFET devices, the epitaxial fill material of the first finFET device having a same height as the epitaxial fill material of the second finFET device.

2. The finFET assembly of claim 1, wherein the first finFET device comprises a first gate structure, the first fins of the first finFET device passing through the first gate structure, and
the second finFET device comprises a second gate structure, the second fins of the second finFET device passing through the second gate structure.

3. The finFET assembly of claim 2, wherein the first height greater than the second height, and
a height of the epitaxial fill material is substantially the same as the first height.

4. The finFET assembly of claim 2, wherein a portion of each fin located within each of the first and second gate structures has a height different than the epitaxial fill material located on portions of the fin located outside the first and second gate structures, respectively.

5. The finFET assembly of claim 2, wherein the epitaxial fill material entirely covers the fins of the first and second finFET devices located outside the first and second gate structures.

6. The finFET assembly of claim 1, wherein the epitaxial fill material includes at least two epitaxial layers.

7. The finFET assembly of claim 6, wherein an upper epitaxial layer of the at least two or more epitaxial layers is doped at a concentration different than a lower epitaxial layer of the at least two epitaxial layers.

8. The finFET assembly of claim 7, wherein the lower epitaxial layer is doped at a lower concentration than the upper epitaxial layer.

9. The finFET assembly of claim 1, wherein each of the first finFET device and the second finFET device comprises a contact on an upper surface of the epitaxial fill material, the contact extending continuously over a plurality of fins.

10. The finFET assembly of claim 9, wherein the contact is a silicide layer.

11-20. (canceled)
